(19) United States
(12) Patent Application Publication
(10) Pub. No.: US 2012/0097859 A1
(43) Pub. Date: Apr. 26, 2012

(54) SEMICONDUCTOR STRUCTURE, PARTICUALARLY BIB DETECTOR, HAVING A DEPFET AS A SENSOR DEVICE, AND CORRESPONDING OPERATING METHOD

(75) Inventors: Gerhard Lutz, Muenchen (DE); Lothar Strueder, Muenchen (DE); Valentin Fedl, Muenchen (DE)

(73) Assignee: Max-Planck-Gesellschaft zur Foerderung der Wissens chaften e.V., Muenchen (DE)

(21) Appl. No.: 13/376,300

(22) PCT Filed: May 12, 2010
(86) PCT No.: PCT/EP2010/002951

§ 371 Date: Jan. 10, 2012

(30) Foreign Application Priority Data
Jun. 3, 2009 (DE) 10 2009 023 807.7

(51) Int. Cl. G01T 1/24; H01L 31/10

(52) U.S. Cl. 250/371; 257/222; 257/E31.053

(57) ABSTRACT

The invention relates to an operating method for a semiconductor structure (1), particularly for a detecting element, in a semiconductor detector, particularly in a blocked impurity band detector, comprising the following steps: a) generating free signal charge carriers (2) in the semiconductor detector by impinging radiation, b) collecting the radiation-generated signal charge carriers (2) in a storage area (IG) in the semiconductor structure (1), wherein the storage area (IG) forms a potential well in which the signal charge carriers (2) are captured, c) deleting the signal charge carriers (2) collected in the storage area (IG) in IG that the signal charge carriers (2) are removed from the storage area (IG), d) generating an electric tunnel field in the area of the storage area (IG), so that the signal charge carriers (2) present in the storage area (IG) can tunnel out of the potential well of the storage area (IG) using the tunnel effect, into a conduction band in which the signal charge carriers (2) are freely displaceable. The invention further relates to a corresponding semiconductor structure.

The invention relates to an operating method for a semiconductor structure, particularly for a readout element (e.g. a DEPFET: Depleted Field Effect Transistor), in a semiconductor detector, particularly in a BIB detector (BIB: Blocked Impurity Band). Furthermore, the invention relates to a correspondingly constructed semiconductor structure.

BIB detectors are known from numerous publications, such as for example EP 0 271 522 A1, EP 0 110 977 B1, EP 0 110 977 A1, US 4 956 687 A, US 4 568 960 A, US 4 507 674 A, WO 1988/00397 A1 and WO 1983/04456 A1.

Furthermore, from FEDL, V. et al.: “Investigation of Single Pixel DePMOSFETs under Cryogenic Conditions” in “Proceedings of the 2008 IEEE Nuclear Science Symposium and Medical Imaging Conference”, a DEPFET is to be used as readout element for BIB detectors of this type, which DEPFET is known from the prior art and is for example described in Gerhard Lutz: “Semiconductor Radiation Detectors”, Springer-Verlag, pages 243-258.

Problematic for the use of a DEPFET as readout element in a BIB detector is the fact that the BIB detector is operated at very low temperatures of up to 5 K, which makes the deletion of the signal charge carriers accumulated in the internal gate of the DEPFET more difficult, as the signal charge carriers can no longer move freely at low temperatures of this type, so that the deletion mechanisms conventionally used in DEPFETs do not function or only function unsatisfactorily. In the previously mentioned publication from FEDL et al., this problem is recognized and the use of a plurality of up to 1000 deletion pulses is suggested in order to compensate the low effectiveness of the individual deletion processes by means of a large number of repeated deletion processes. This known solution of the problem of insufficient deletion in the case of extremely low temperatures is unsatisfactory however.

The invention is therefore based on the object of specifying a deletion mechanism, which makes it possible in the case of a DEPFET to effectively delete the signal charge carriers accumulated in the internal gate of the DEPFET even at extremely low temperatures and to remove the same from the internal gate.

This object is achieved by means of an operating method according to the invention and by a correspondingly designed semiconductor structure according to the independent claims.

The invention is based on the technical physical insight that the signal charge carriers accumulated in the internal gate of the DEPFET at very low temperatures are generally captured in a potential well at an impurity site so that the signal charge carriers cannot move freely, which prevents a removal of the signal charge carriers from the internal gate or at least make the same more difficult.

The invention therefore comprises the general technical teaching of freeing the signal charge carriers from their potential wells in the internal gate of the DEPFET by means of the tunnel effect which is known per se. The invention therefore makes provision for an electrical tunnel field to be generated in the area of the internal gate, so that the signal charge carriers located in the potential well of the internal gate can tunnel out of the potential well of the internal gate into a conduction band using the tunnel effect, in which the signal charge carriers can then move freely, which enables a removal of the signal charge carriers from the internal gate.

The tunnel field can in the case of a transistor structure for example be generated by a suitable electrical control of source, drain and/or gate of the transistor structure. The invention is not limited to semiconductor structures of this type however, in the case of which the tunnel field is generated by means of the contacts (e.g. gate, source, drain) of the semiconductor structure, which are present in any case. Rather, it is also conceivable that the semiconductor structure according to the invention has one or more additional contacts in order to generate the tunnel field.

The idea according to the invention of mobilizing signal charge carriers by means of the tunnel effect is not only realizable in the case of DEPFETs which are used as readout element in a semiconductor detector. Rather, the principle according to the invention of using the tunnel effect for mobilizing stored signal charge carriers can also be realized in general terms in the case of semiconductor structures which are used as readout element in a BIB detector. Furthermore, the principle according to the invention of using the tunnel effect can also be used generally in semiconductor structures, which have a storage area in which radiation-generated signal charge carriers are accumulated.

As an example for such an application of the principle according to the invention, mention may be made of CCD detectors (CCD: Charge Coupled Devices), which are known per se from the prior art and therefore do not need to be described in more detail.

Furthermore, the invention can also be realized in the case of a floating gate amplifier, as is described for example in R. P. KRAFT et al.: “Soft X-ray spectroscopy with sub-electron readnoise charge coupled devices”, Nuclear Instruments and Methods in Physics Research Section A, v. 361, p. 372-383.

Further, in the context of the invention, there is the possibility that the semiconductor detector is an RNDR detector (RNDR: Repetitive non-destructive read-out), as is known per se from the prior art (cf. S. WÖLFEL et al.: “A novel way of single optical photon detection: Beating the 1/f noise limit with ultra high resolution DEPFET-RNDR devices”, IEEE-TNS Vol 54, No 4, Part 3 (2007) 1311-1318).

Particularly advantageous is the realization of the principle according to the invention, however, in the case of semiconductor structures which are operated at very low temperatures of up to 5 K, as the signal charge carriers can otherwise also be deleted in the conventional manner.

Furthermore, the concept according to the invention for deleting the signal charge carriers from the storage area (e.g. the internal gate of a DEPFET) preferably makes provision for the signal charge carriers tunneled out of the potential well into the conduction band by means of the tunnel effect to drift out of the storage area. Theoretically, it is possible in the context of the invention that the signal charge carriers tunneled into the conduction band only leave the storage area by diffusion processes. However, the movement of the signal charge carriers out of the storage area is preferably supported in a targeted manner by an electrical drift field, which is designated as a deletion field in the context of the invention and is generated by means of a deletion contact.

The generation of deletion fields of this type is known per se from conventional DEPFETS and therefore does not need to be described in more detail.

In the case of the concept according to the invention for deleting the signal charge carriers accumulated in the storage area, there is the possibility that the signal charge carriers tunneled into the conduction band are again captured after a short distance by an impurity site in the semiconductor structure, as a result of which the deletion process is hindered. The invention therefore preferably makes provision for the deletion of the signal charge carriers to be repeated a number of times, in order to remove as many signal charge carriers as possible from the storage area.

Here, it is to be taken into account that the tunnel field generates a potential well at the location of an impurity site in each case, so that the spatial location of the potential well of the tunnel field should be spatially displaced between the successive deletion processes, in order to prevent signal electrons from being captured by the impurity sites again.

This spatial displacement of the potential well of the tunnel field between the successive deletion processes can take place in a different direction. For example, the potential well of the tunnel field in the semiconductor structure can be displaced in the lateral direction essentially parallel to the current direction or to the conductor channel of the transistor structure. Alternatively, there is the possibility that the potential well of the tunnel field is displaced in the lateral direction essentially transversely and preferably perpendicularly to the current direction or to the conductor channel of the transistor current. Further, there is the possibility that the potential well of the tunnel field is displaced in the vertical direction between the successive deletion processes. Furthermore, there is the possibility of a combination of the previously listed variants for displacing the potential well of the tunnel field between the successive deletion processes.

It has previously already been mentioned that the storage area is preferably an internal gate of a transistor structure, wherein the signal charge carriers accumulated in the internal gate control the transistor current. The previously mentioned deletion or drift field can here optionally be orientated transversely to the current direction of the transistor current or transversely to the conductor channel of the transistor structure, so that the signal charge carriers drift transversely to the conductor channel in the context of a deletion process. Alternatively, there is the possibility that the deletion field is orientated essentially parallel to the current direction of the transistor current or the conductor channel of the transistor structure, so that during deletion, the signal charge carriers drift essentially parallel to the current direction of the transistor current.

In the preferred exemplary embodiment of the invention, a deletion contact is provided for generating the deletion field, as is the case for conventional DEPFETs. Depending on the desired drift direction when deleting, with respect to the current direction of the transistor current, the deletion contact can optionally be arranged laterally adjacent to the conductor channel or in the channel direction upstream or downstream of the transistor structure.

The mechanism according to the invention for deleting the signal charge carriers accumulated in the storage area operates even at extremely low temperatures, as has already been mentioned previously. In the context of the invention, provision is therefore preferably made for the semiconductor detector (e.g. a BIB detector) and/or the semiconductor structure (e.g. a readout element, particularly in the form of a DEPFET) to be cooled to a temperature of less than 100 K, 50 K, 30 K, 20 K or even less than 10 K.

In addition to the previously described operating method according to the invention, the invention also comprises a correspondingly designed semiconductor structure with a deletion apparatus which generates the previously mentioned tunnel field.

Furthermore, the deletion apparatus preferably also has a deletion contact in order to generate the previously mentioned drift or deletion field in the semiconductor structure.

Other advantageous developments of the invention are characterized in the dependent claims or will be explained in more detail below together with the description of the preferred exemplary embodiments of the invention, with reference to the figures. The figures show as follows:

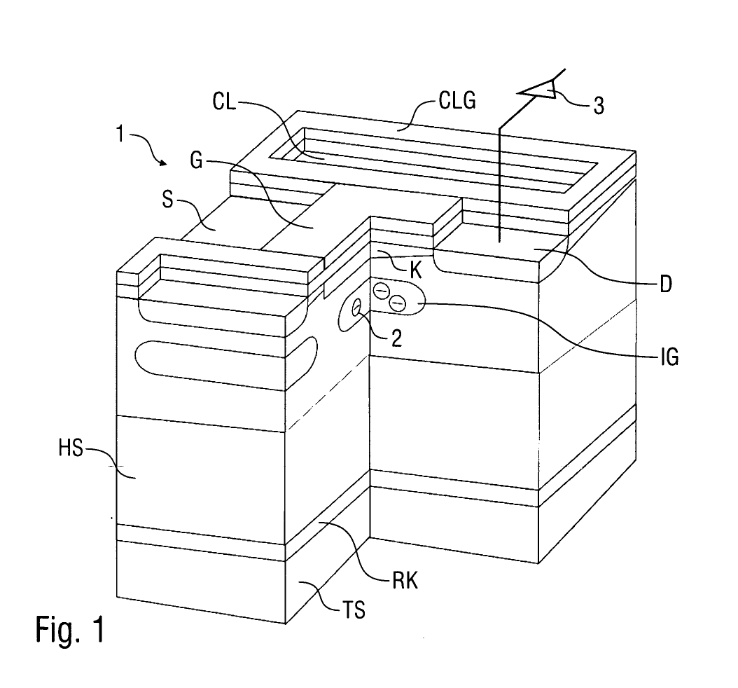

FIG. 1 a cut open perspective view of a DEPFET, which is used as readout element of a BIB detector,

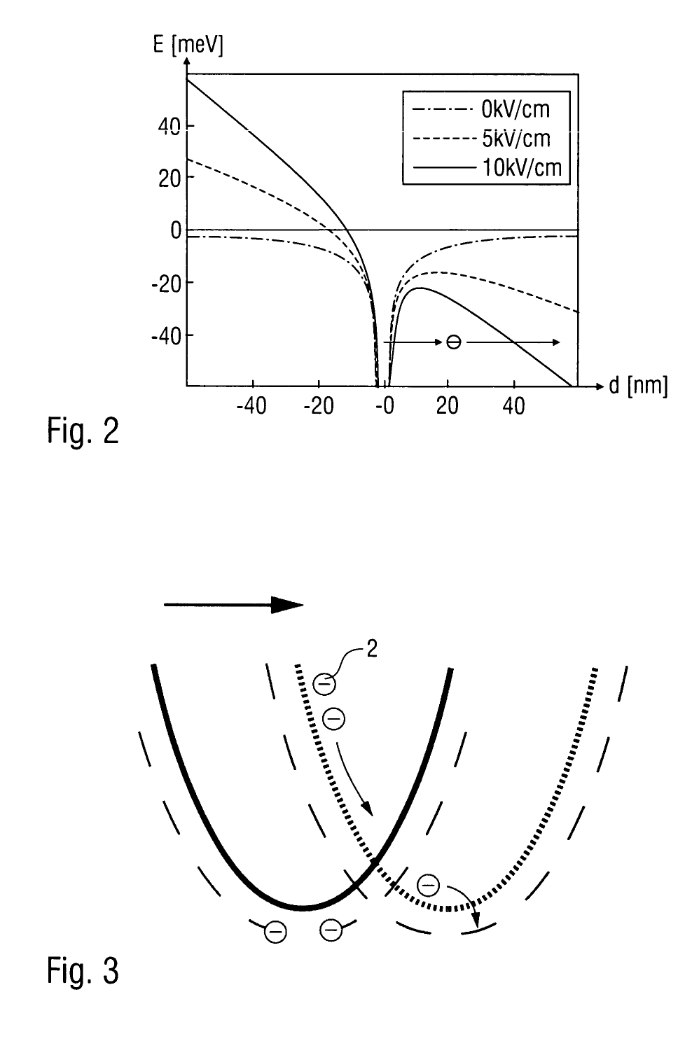

FIG. 2 a micro-potential well at an impurity site in dependence on the field strength prevailing in the vicinity of the impurity site,

FIG. 3 various states of the macro-potential well in the internal gate of the DEPFET according to FIG. 1,

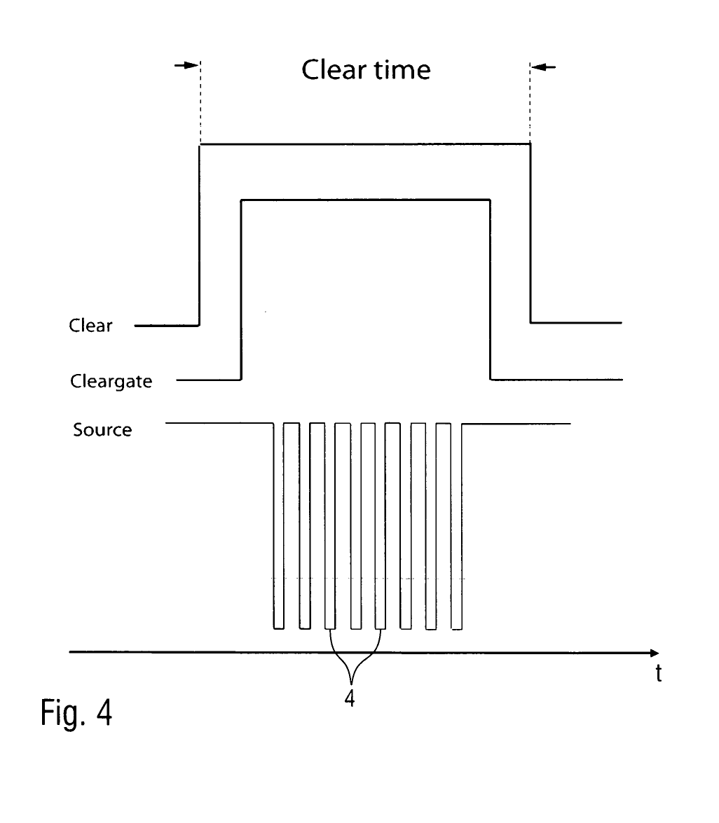

FIG. 4 the temporal course of the voltages applied to the external electrodes (source, clear gate and clear) at the DEPFET according to FIG. 1 during deletion,

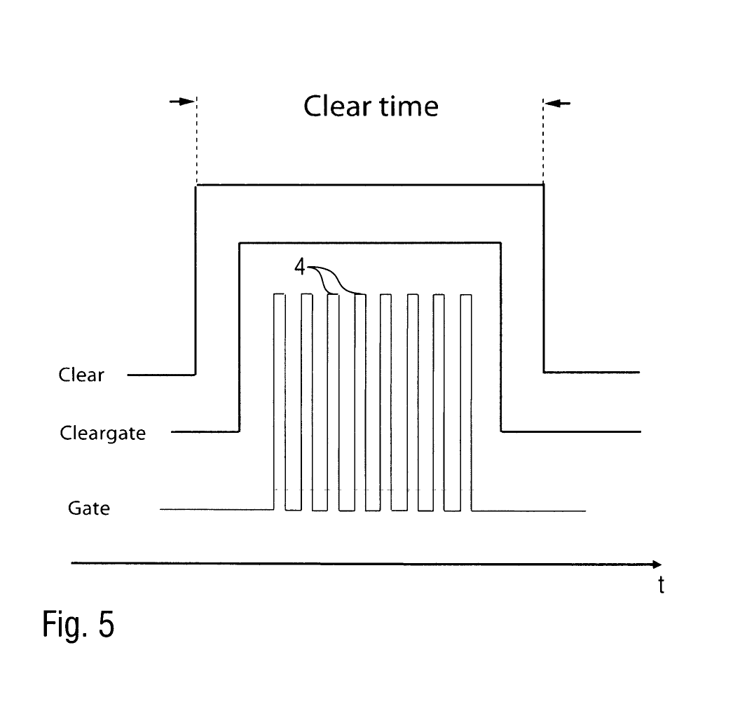

FIG. 5 alternative possible courses of the voltages applied to the external electrodes (gate, clear gate and clear),

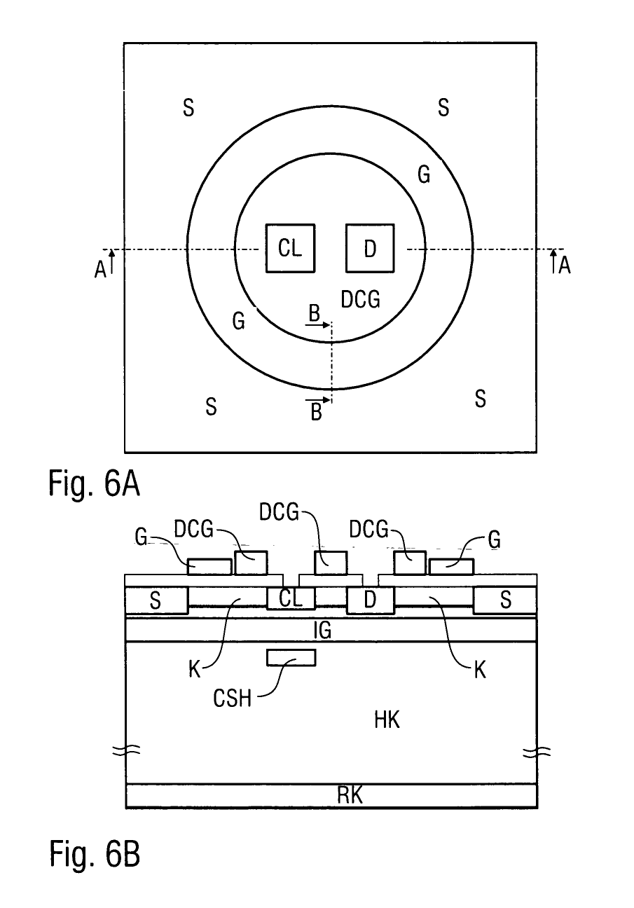

FIG. 6A a plan view onto an annular DEPFET,

FIG. 6B a cross-sectional view through the DEPFET according to FIG. 6A along the line A-A,

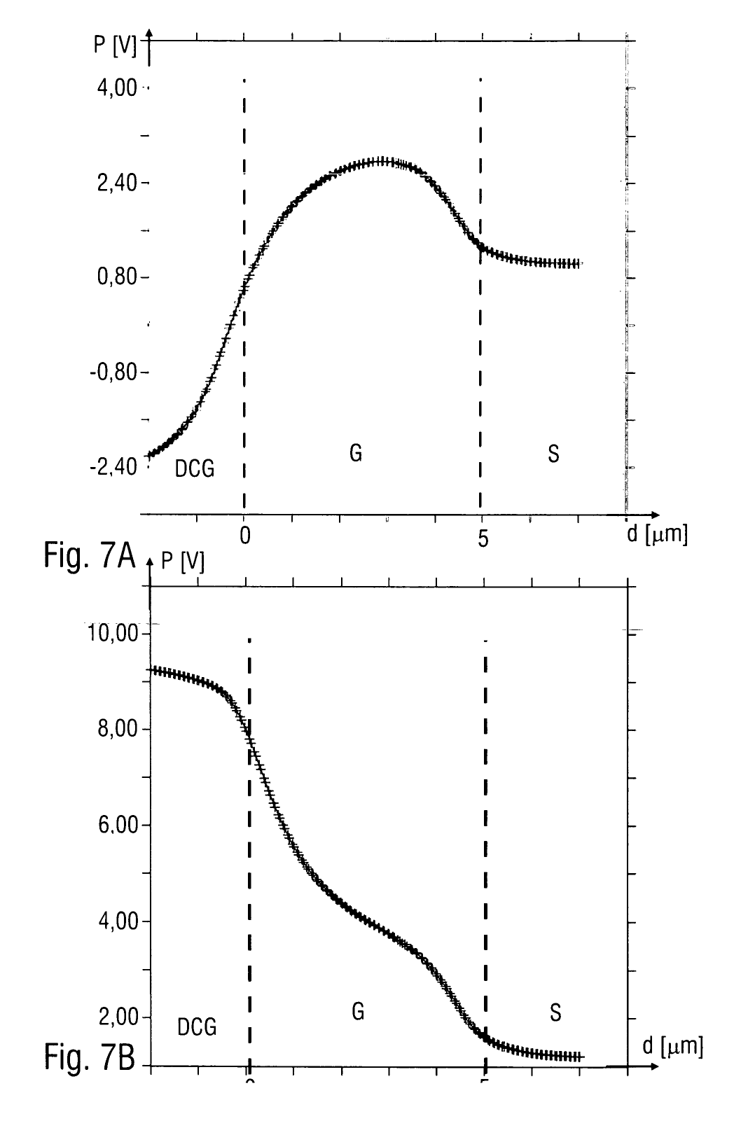

FIG. 7A the course of the electrical potential in the DEPFET according to the FIGS. 6A and 6B along the line B-B in FIG. 6B without a tunnel field,

FIG. 7B the course of the electrical potential in the DEPFET according to the FIGS. 6A and 6B along the line B-B in FIG. 6B with a tunnel field,

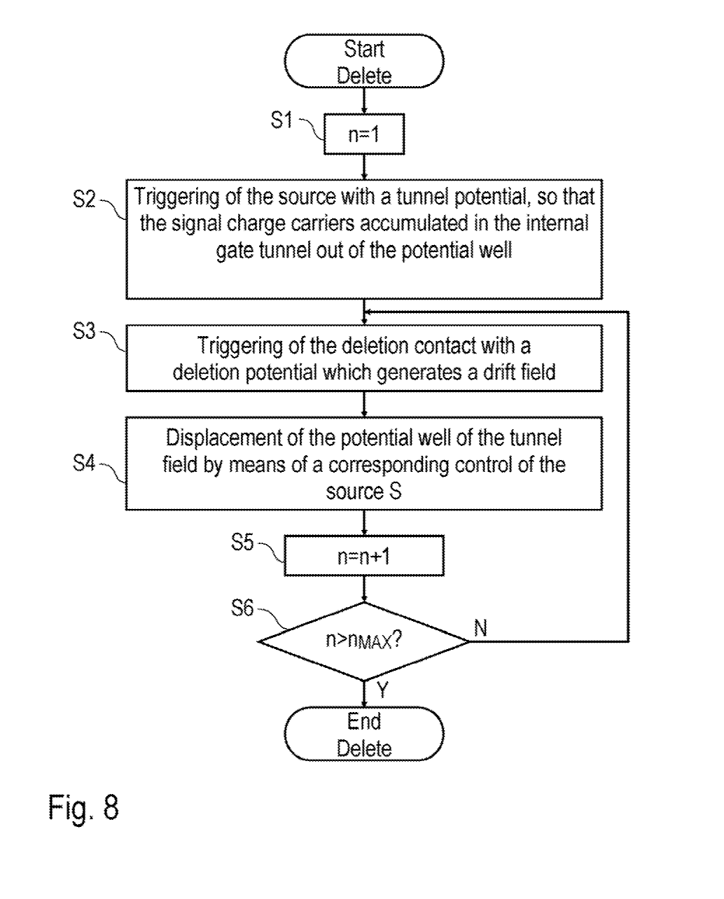

FIG. 8 the deletion method according to the invention in the form of a flow diagram, and also

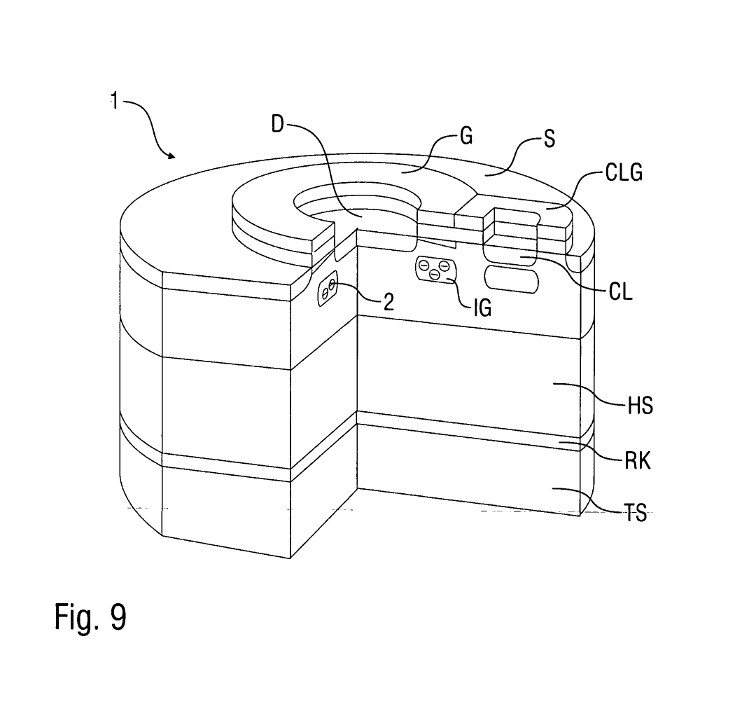

FIG. 9 a perspective and partially cut-open view of an annular DEPFET.

FIG. 1 shows a DEPFET 1 (DEPFET: Depleted Field Effect Transistor), which is used as a readout element for a BIB detector (BIB: Blocked Impurity Band), wherein the BIB detector is not illustrated for the sake of simplification.

BIB detectors of this type are known however per se from the prior art, so that with respect to the structure and the mode of operation of BIB detectors, reference is made to the documents cited at the beginning.

The structure and the mode of operation of the illustrated DEPFET 1 are to a large extent conventional, so that with respect to the structure and the mode of operation of DEPFET 1, reference is made to the documents cited at the beginning.

It is only to be mentioned briefly here that the DEPFET 1 has a semiconductor substrate HS which is depleted and strongly n-doped in operation and is delimited on its underside by a strongly n-doped rear contact RK, an intrinsic carrier substrate TS, which achieves the required mechanical stability, adjoining the rear contact RK.

At its upper side, the DEPFET 1 has a strongly p-doped source S and a strongly p-doped drain D, a conductor channel K extending between the source S and the drain D, through which conductor channel a controllable transistor current flows during operation.

On the one hand, the transistor current flowing through the conductor channel K is controlled by an external gate G which is located on the upper side of the DEPFET 1 above the conductor channel K.

On the other hand, the transistor current flowing through the conductor channel K can be controlled by an internal gate IG which is embedded in the semiconductor substrate HS under the conductor channel K. During the operation of the DEPFET 1 as readout element of a BIB detector, radiation-generated signal charge carriers 2 accumulate in the internal gate IG, so that the signal charge carriers 2 accumulated in the internal gate IG likewise control the transistor current through the conductor channel K, which therefore forms a measure for the detected radiation.

Furthermore, the drain D is connected to an amplifier 3 which is here only illustrated schematically.

Furthermore, the DEPFET 1 has a deletion apparatus in order to delete the signal charge carriers 2 accumulated in the internal gate IG, i.e. to remove the same from the internal gate IG. The deletion apparatus essentially consists of a clear gate CLG and a strongly n-doped deletion area CL. The deletion apparatus enables the generation of a deletion or drift field in the DEPFET 1 by means of a suitable potential loading of the clear gate CLG and the deletion area CL, wherein the deletion field is orientated transversely to the conductor channel K so that the signal charge carriers 2 drift transversely to the conductor channel K out of the internal gate IG during deletion.

FIG. 2 now shows the course of a potential well which arises in the internal gate IG at an impurity site. Here, various courses of the micro-potential well are illustrated for various field strengths which are generated by means of a tunnel field in the DEPFET 1.

The dot-dashed line here shows the course of the potential well without a tunnel field. In this state, the signal charge carriers 2 are captured in the micro potential well and cannot be removed or can only be removed from the internal gate IG with a very low probability.

The dashed curve by contrast shows the course of the micro-potential well with a relatively weak tunnel field with a field strength of 5 kV/cm. From this it can be seen that the potential well is distorted, as a result of which the statistical probability is increased and that the signal charge carriers 2 tunnel out of the potential well into the conduction band.

Finally, the solid line shows the course of the potential well with a tunnel field of 10 kV/cm. In the case of a tunnel field of this type, the signal charge carriers 2 can tunnel out of the potential well into the conduction band, where the signal charge carriers 2 can then move freely, which is used in the context of the invention for clearing the internal gate IG.

The tunnel field illustrated with a solid line in FIG. 2 therefore enables a deletion of the signal charge carriers 2 accumulated in the internal gate IG, even at the very low temperatures of up to 5 K, which are necessary during operation of the BIB detector.

FIG. 3 shows the displacement of the macroscopic potential well in the internal gate IG of the DEPFET 1, wherein the displacement can be caused by an applied voltage at the source S and/or at the external gate G and/or another external electrode. The coarsely dashed lines should here indicate flat impurity sites in which the signal charge carriers 2 freeze out at the low temperatures which are required during the operation of the BIB detector. These signal charge carriers 2 can be emitted into the conduction band by means of a satisfactorily high electrical field. The macroscopic potential well is displaced by means of a voltage applied from outside (indicated by the finely dashed line). This means that at the site where the potential minimum was previously, a high field results, which causes the signal charge carriers 2 to tunnel into the conduction band. As the signal charge carriers 2 can now move freely into the conduction band, they drift to the new potential minimum and there freezes out once more. In this case, it is ensured that the signal charge carriers 2 can diffuse or drift in the vertical direction (not illustrated here) to a deletion contact. By means of multiple repetition, the dwell time of the signal charge carriers 2 in the conduction band increases, as a result of which the internal gate IG is deleted.

FIG. 4 shows the course of the electrical potentials at the deletion area CL, the clear gate CLG or the source S of the DEPFET 1 according to FIG. 1 during the deletion of the internal gate IG.

The loading of the source S with numerous deletion pulses 4 generates a tunnel field in the DEPFET 1 in each case, so that the signal charge carriers 2 accumulated and frozen out in the internal gate IG can tunnel into the conduction band, this process being repeated a number of times in accordance with the number of deletion pulses 4.

The loading of the clear gate CLG and the deletion area CL is by contrast used to generate a deletion or drift field in the DEPFET 1, which is orientated transversely to the conductor channel K so that the signal electrons 2 drift transversely to the conductor channel K out of the internal gate IG.

FIG. 5 shows an alternative for the loading of the deletion area CL, the clear gate CLG and the gate G in the case of the DEPFET 1 for deleting the internal gate IG.

By contrast with the variant according to FIG. 4, the tunnel field is therefore not generated by a loading of the source S here, but rather by a loading of the gate G.

The FIGS. 6A and 6B show an alternative exemplary embodiment of a DEPFET 1 which is described in detail in DE 10 2004 003 283 A1, so that the content of this published document is to be included in the present description in full with regards to the mode of operation and the structure of the DEPFET 1.

In this exemplary embodiment of the DEPFET 1 also, a tunnel field can be generated by the previously described electrical control of the gate G, the source S and/or the drain clear gate DCG, so that, for deletion, the signal charge carriers stored in the internal gate IG can tunnel into the conduction band where they can move freely.

FIG. 7A shows the course of the electrical potential in the DEPFET 1 without a tunnel field according to the invention below the gate G along the line B-B in FIG. 6A, the X axis representing the space of the border between the drain clear gate DCG and the gate G. From this illustration, it can be seen that a potential well forms in the DEPFET 1 within the internal gate IG between the drain clear gate DCG and the source S, in which potential well signal electrons are captured.

By contrast, FIG. 7B shows the course of the potential P along the line B-B in FIG. 6A with a tunnel field which is generated by a suitable electrical triggering of the source S, the gate G and/or the drain clear gate DCG. The signal charge carriers 2 accumulated in the internal gate IG can then tunnel into the conduction band and can move freely there in order to drift to the clear area CL.

FIG. 8 shows the deletion method according to the invention in the form of a flow diagram.

In a first step S1, an internal counter n=1 is initially reset, in order to be able to count the number of deletion processes.

In a following step S2, the source S is then triggered with a tunnel potential so that the signal charge carriers 2 accumulated in the internal gate IG can tunnel out of the potential well into the conduction band, where the signal charge carriers 2 can then move freely. The step S2 thus corresponds to the variant according to FIG. 3, according to which the source S is triggered in order to generate the tunnel field. Alternatively, it is also possible, however, to trigger the gate G in accordance with FIG. 5 in step S2, in order to generate the tunnel field.

In a following step S3, the clear gate CLG and the deletion area CL are then triggered in accordance with FIG. 4, in order to generate a deletion or drift field.

In the following step S4, the tunnel field is then correspondingly displaced in order to allow signal charge carriers to tunnel into the conduction band, which signal charge carriers were captured by an impurity site again.

In the next step S5, the counter n is then incremented.

In the following step S6, a check is then performed as to whether the counter n has exceeded a predetermined maximum value n_{MAX}.

The previously outlined deletion processes are then repeated correspondingly often, in order to delete all of the signal charge carriers 2 from the internal gate IG.

FIG. 9 shows a modification of the DEPFET 1 according to FIG. 1, so that in order to avoid repetitions, reference is made to the previous description, the same reference numerals being used for corresponding details.

A particularity of this exemplary embodiment consists in the fact that the DEPFET 1 is annular, whereas the DEPFET 1 according to FIG. 1 is linearly constructed.

In this exemplary embodiment of the DEPFET 1 also, a tunnel field can be generated by the previously described electrical control of the gate G and/or the source S, so that, for deletion, the signal charge carriers stored in the internal gate IG can tunnel into the conduction band where they can move freely.

The invention is not limited to the preferred exemplary embodiments described above. Instead, many variants and modifications are possible, which also make use of the concept of the invention and thus fall within the scope of protection.

### LIST OF REFERENCE NUMERALS

1 DEPFET
2 Signal charge carriers
3 Amplifier
4 Deletion pulses
CL Deletion area
CLG Clear gate
D Drain
DCG Drain clear gate
G External gate
HS Semiconductor substrate
IG Internal gate
K Conductive channel
RK Back contact
S Source
TS Carrier substrate

1. Operating method for a semiconductor structure in a semiconductor detector, wherein the operating method comprises the following steps:
a) generating free signal charge carriers in the semiconductor detector by use of incident radiation,
b) collecting the radiation-generated signal charge carriers in a storage area in the semiconductor structure, wherein the storage area forms a potential well in which the signal charge carriers are captured, and
c) deleting the signal charge carriers, which are accumulated in the storage area, in that the signal charge carriers are removed from the storage area, wherein the deleting step comprises generating an electrical tunnel field in an area of the storage area, so that the signal charge carriers located in the potential well of the storage area can tunnel out of the potential well of the storage area into a conduction band using the tunnel effect, in which the signal charge carriers can move freely.

2. Operating method according to claim 1, wherein the step for deleting the signal charge carriers further comprises a step of drifting of the signal charge carriers tunneled into the conduction band out of the storage area.

3. Operating method according to claim 2, wherein the step for deleting the signal charge carriers further comprises generating an electrical deletion field in the semiconductor structure by way of a deletion contact, wherein the deletion field lets the signal charge carriers tunneled out of the storage area into the conduction band drift out of the storage area.

4. Operating method according to claim 1, wherein the deletion of the signal charge carriers is repeated a number of times, in order to remove possibly all signal charge carriers from the storage area.

5. Operating method according to claim 4, wherein:
a) the tunnel field generates a potential well at an impurity site,
b) a spatial location of the potential well of the tunnel field is spatially displaced between the successive deletion processes, in order to prevent signal charge carriers from being captured by the impurity sites again.

6. Operating method according to claim 1, wherein:
a) as an internal gate, the storage area is a constituent of a transistor structure with a controllable transistor current with a defined current direction, and
b) that the signal charge carriers accumulated in the internal gate control the transistor current.

7. Operating method according to claim 6, wherein the deletion field is orientated essentially transversely to the current direction of the transistor current, so that during deletion, the signal charge carriers are orientated transversely to the current direction of the transistor current, so that during deletion, the signal charge carriers drift transversely to the current direction.

8. Operating method according to claim 7, wherein:
a) a deletion contact is provided for generating the deletion field, and
b) with respect to the current direction of the transistor current, the deletion contact is arranged laterally adjacent to the transistor structure.

9. Operating method according to claim 5, wherein the spatial displacement of the potential well of the tunnel field between the successive deletion processes takes place in one of the following directions:
a) in the lateral direction essentially parallel to the current direction of the transistor current,
b) in the lateral direction essentially transversely to the current direction of the transistor current, or
c) in the vertical direction.

10. Operating method according to claim 1, wherein
a) the internal gate is a constituent of a transistor structure, wherein the internal gate is embedded in the semiconductor structure, and
b) in addition to the internal gate, the transistor structure has a source, a drain, a controllable conductor channel between the source and the drain and an external gate, and
c) the signal charge carriers accumulated in the internal gate control the transistor current through the conductor channel, and
d) the potential of the external gate controls the transistor current through the conductor channel, and
e) the tunnel field is generated in such a way that a corresponding tunnel voltage is applied to the source of the transistor structure.

11. Operating method according to claim 1, wherein the semiconductor detector is a blocked impurity band detector, which is operated in a deep-frozen state.

12. Operating method according to any claim 1, wherein:
a) the semiconductor structure is a readout element of the semiconductor detector, and
b) the readout element emits an electrical output signal depending on the signal charge carriers accumulated in the internal gate, and
c) the output signal is a measure for the detected radiation.

13. Operating method according to claim 1, further comprising the following step:
deep freezing of the semiconductor detector and/or the semiconductor structure,

14. Semiconductor structure for a semiconductor detector for radiation detection, comprising:
a) a semiconductor substrate,
b) a storage area embedded in the semiconductor substrate for collecting radiation-generated signal charge carriers, wherein the storage area forms a potential well in which the signal charge carriers are captured,
c) a deletion apparatus for removing the signal charge carriers accumulated in the storage area from the storage area,
wherein the deletion apparatus generates an electrical tunnel field in the area of the storage area, so that the signal charge carriers located in the potential well of the storage area can tunnel out of the potential well into a conduction band using the tunnel effect, in which the signal charge carriers can move freely.

15. Semiconductor structure according to claim 14, wherein:
a) the deletion apparatus generates an electrical deletion field in the semiconductor structure by way of a deletion contact,
b) the deletion field lets the signal charge carriers tunneled out of the storage area into the conduction band drift out of the storage area.

16. Semiconductor structure according to claim 14, wherein:
a) the tunnel field has a potential well at an impurity site,
b) the deletion apparatus spatially displaces the spatial location of the potential well of the tunnel field between the successive deletion processes, in order to prevent signal charge carriers from being captured at the impurity sites again.

17. Semiconductor structure according to claim 14, wherein:
a) as an internal gate, the storage area is a constituent of a transistor structure with a controllable transistor current with a defined current direction, and
b) the signal charge carriers accumulated in the internal gate control the transistor current.

18. Semiconductor structure according to claim 17, wherein the deletion field is orientated essentially transversely to the current direction of the transistor current, so that during deletion, the signal charge carriers diffuse transversely to the current direction of the transistor current.

19. Semiconductor structure according to claim 17, wherein the deletion apparatus changes the spatial location of the potential well of the tunnel field between the successive deletion processes in one of the following directions:
a) in the lateral direction essentially parallel to the current direction of the transistor current,
b) in the lateral direction essentially transversely to the current direction of the transistor current,
c) in the vertical direction.

20. Semiconductor structure according to claim 14, wherein:
a) a deletion contact is provided for generating the deletion field, and
b) with respect to the current direction of the transistor current, the deletion contact is arranged laterally adjacent to the transistor structure.

21. Semiconductor structure according to claim 14, wherein:
a) the internal gate is a constituent of a transistor structure, wherein the internal gate is embedded in the semiconductor structure
b) in addition to the internal gate, the transistor structure has a source, a drain, a controllable conductor channel between the source and the drain and an external gate,
c) the signal charge carriers accumulated in the internal gate control the transistor current through the conductor channel, and
d) the potential of the external gate controls the transistor current through the conductor channel, and
e) the tunnel field is generated in such a way that a corresponding tunnel voltage is applied to the source of the transistor structure.

22. Semiconductor structure according to claim 14, wherein the semiconductor structure is linear.

23. Semiconductor structure according to claim 14, wherein the semiconductor structure is deep frozen.

24. Semiconductor structure according to claim 1, wherein the semiconductor structure is a floating gate amplifier.

25. Semiconductor detector with a semiconductor structure according to claim 14.

26. Semiconductor detector according to claim 25, wherein:
a) the semiconductor structure is a readout element of the semiconductor detector, and
b) the readout element emits an electrical output signal depending on the signal charge carriers accumulated in the internal gate, and
c) the output signal is a measure for the detected radiation.

27. Semiconductor detector according to claim 25, wherein the semiconductor detector is a blocked impurity band detector, which is operated in a deep-frozen state.

28. Operating method according to claim 6, wherein the deletion field is orientated essentially parallel to the current direction of the transistor current, so that during deletion, the signal charge carriers drift essentially parallel to the current direction of the transistor current.

29. Operating method according to claim 7, wherein:
a) a deletion contact is provided for generating the deletion field, and
b) with respect to the current direction of the transistor current, the deletion contact is arranged upstream or downstream of the transistor structure.

30. Operating method according to claim 1, wherein the semiconductor detector is a CCD detector.

31. Semiconductor structure according to claim 17, wherein the deletion field is orientated essentially parallel to the current direction of the transistor current, so that during deletion, the signal charge carriers diffuse essentially parallel to the current direction of the transistor current.

32. Semiconductor structure according to claim 14, wherein:
a) a deletion contact is provided for generating the deletion field, and
b) with respect to the current direction of the transistor current, the deletion contact is arranged upstream or downstream of the transistor structure.

33. Semiconductor structure according to claim 14, wherein the semiconductor structure is annular.

34. Semiconductor detector according to claim 25, wherein the semiconductor detector is a CCD detector.

35. Semiconductor detector according to claim 25, wherein the semiconductor detector is a RNDR detector.
